(19) United States
(12) Patent Application Publication
(10) Pub. No.: US 2026/0293214 A1
(43) Pub. Date: Sep. 24, 2026

(54) TELLURIUM OXIDE SEMICONDUCTOR THIN-FILM TRANSISTOR COMPRISING TELLURIUM INTERLAYER AND METHOD FOR MANUFACTURING THE SAME

(71) Applicant: POSTECH RESEARCH AND BUSINESS DEVELOPMENT FOUNDATION, Pohang-si (KR)

(72) Inventors: Yong-Young NOH, Pohang-si (KR); Jaeyun LEE, Pohang-si (KR)

(21) Appl. No.: 19/568,955

(22) Filed: Mar. 17, 2026

(30) Foreign Application Priority Data
Mar. 21, 2025 (KR) 10-2025-0036606

(51) Int. Cl. H10D 30/67; H10D 30/01

(52) U.S. Cl. CPC H10D 30/6756; H10D 30/0316; H10D 30/6732; H10D 30/6739; H10D 30/675

(57) ABSTRACT

Disclosed is a tellurium oxide semiconductor thin-film transistor comprising tellurium interlayer and method for manufacturing the same. In detail, present disclosure relates to a thin-film transistor, the thin-film transistor comprising: a semiconductor layer comprising a tellurium-based amorphous p-type semiconductor; a source electrode and a drain electrode located spaced apart from each other; and an interlayer comprising a first interlayer located between the semiconductor layer and the source electrode and a second interlayer located between the semiconductor layer and the drain electrode, wherein the first interlayer and the second interlayer each independently comprise at least one interlayer element selected from the group consisting of a Group 14 element, a Group 15 element, and a Group 16 element of the periodic table. The present disclosure has the effect of providing a TFT exhibiting excellent electrical performance with improved electron field effect mobility and on-current value by comprising a interlayer.

### CROSS REFERENCE TO RELATED APPLICATION

The present application claims priority to Korean Patent Application No. 10-2025-0036606, filed on Mar. 21, 2025, and the entire contents of which are incorporated herein for all purposes by this reference.

### BACKGROUND OF THE DISCLOSURE

### 1. Field of the Disclosure

The present disclosure relates to a tellurium oxide semiconductor thin-film transistor comprising tellurium interlayer and method for manufacturing the same.

### 2. Description of the Related Art

Amorphous semiconductors have the advantages of lower manufacturing costs and the ability to be mass-produced uniformly compared to crystalline semiconductors. However, conventional hydrogenated amorphous silicon (a-Si:H) has poor electrical properties, which limits its performance, especially in p-channel materials. On the other hand, while materials such as a-InGaZnO, an n-channel oxide semiconductor that can realize high-speed mobility, have driven progress, finding a p-channel material remains a major challenge. This is acting as a major cause hindering the development of CMOS technology and complementary electronic circuits.

Meanwhile, tellurium oxide (TeOₓ) is originally evaluated as a p-channel semiconductor with excellent electrical properties, but it has the characteristic of being difficult to naturally maintain a high hole concentration. To overcome this limitation, conventionally, a method of alloying selenium (Se) into TeOₓ has been applied. TeOₓ doped with Se recorded a hole mobility of approximately 15 cm²/V·s, which was unprecedented in conventional amorphous p-channel semiconductors and one of the highest levels achievable in amorphous p-channel semiconductors. This achievement plays a significant role in dramatically improving the overall performance of p-type thin-film transistors (TFTs) and has overcome the limitations of conventional p-channel semiconductors. However, while alloyed TeOₓ semiconductors exhibit excellent hole mobility, they still have to overcome the problem of the high contact resistance to achieve higher performance. The contact resistance between the semiconductor and the electrodes restricts the flow of electrons and has significantly impact on the overall efficiency of the device. In particular, in p-channel semiconductors, insufficient conductivity and incomplete contact with electrodes can act as the main causes of performance degradation.

Therefore, in order to increase the driving voltage and reduce the power consumption of semiconductor devices, research is needed to minimize contact resistance, and the development of new electrode materials or surface treatment technologies that can induce high interactions between the electrodes and the semiconductors is essential.

### SUMMARY OF THE DISCLOSURE

The purpose of the present disclosure is to solve the above problems, and to provide a TeOₓ semiconductor thin-film transistor with improved contact resistance through the insertion of an interlayer.

Another purpose of the present disclosure is to provide a method for manufacturing a TeOₓ semiconductor thin-film transistor by forming an interlayer on the TeOₓ semiconductor thin-film transistor using a thermal evaporation deposition technique.

One aspect of the present disclosure provides a thin-film transistor, the thin-film transistor 10 comprising: a semiconductor layer 100 comprising a tellurium-based amorphous p-type semiconductor; a source electrode 200 and a drain electrode 300 located spaced apart from each other; and an interlayer 400 comprising a first interlayer 410 located between the semiconductor layer 100 and the source electrode 200 and a second interlayer 420 located between the semiconductor layer 100 and the drain electrode 300, wherein the first interlayer 410 and the second interlayer 420 each independently comprise at least one interlayer element selected from the group consisting of a Group 14 element, a Group 15 element, and a Group 16 element of the periodic table.

In addition, the interlayer element may comprise at least one element selected from the group consisting of tellurium (Te), bismuth (Bi), antimony (Sb), and selenium (Se).

In addition, the tellurium-based amorphous p-type semiconductor may comprise a chalcogen atom comprising at least one selected from the group consisting of a selenium (Se) atom and a sulfur (S) atom; and a tellurium composite comprising a tellurium (Te) atom and a tellurium oxide.

In addition, the chalcogen atom may be alloyed with the tellurium composite.

In addition, the tellurium-based amorphous p-type semiconductor may be represented by Chemical Formula 1.

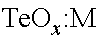

wherein in Chemical Formula 1, M is a sulfur (S) atom or a selenium (Se) atom, and x is 0.8≤x≤1.7.

In addition, the tellurium oxide may comprise a tellurium monoxide (TeO) and a tellurium dioxide (TeO₂).

In addition, the tellurium atom of the tellurium-based amorphous p-type semiconductor may comprise an ionization state of Te⁴⁺, and an ionization state of Te²⁺ and a non-ionization state of Te⁰.

In addition, the selenium atom (Se) may comprise an ionization state of Se²⁻.

In addition, the semiconductor may be in an oxygen-deficient state.

In addition, the source electrode may comprise at least one selected from the group consisting of gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotube (CNT), silver nanowire (Ag NW), indium tin oxide (ITO), and poly(3,4-ethylenedioxythiophene) polystyrene sulfonate (PEDOT:PSS).

In addition, the drain electrode may comprise at least one selected from the group consisting of gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotube (CNT), silver nanowire (Ag NW), indium tin oxide (ITO), and poly(3,4-ethylenedioxythiophene) polystyrene sulfonate (PEDOT:PSS).

In addition, the thin-film transistor may further comprise a gate electrode 500, and the gate electrode 500 may comprise at least one selected from the group consisting of n-doped silicon (n-doped Si), p-doped silicon (p-doped Si), gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotubes (CNT), silver nanowires (Ag NW), indium tin oxide (ITO), and poly(3,4-ethylenedioxythiophene) polystyrene sulfonate (PEDOT:PSS).

In addition, the thin-film transistor may further comprise an insulating layer 600 between the semiconductor layer 100 and the gate electrode 500, and the insulating layer 600 may comprise at least one selected from the group consisting of silicon dioxide, glass, quartz, alumina, silicon carbide, magnesium oxide, polyethylene naphthalate (PEN), polyethylene terephthalate (PET), polystyrene (PS), polyimide (PI), polyvinyl chloride (PVC), polyvinylpyrrolidone (PVP), polyethylene (PE), silicon oxide (SiO₂), germanium, polyvinyl alcohol (PVA), polymethyl methacrylate (PMMA), zirconium oxide (ZrO₂), aluminum oxide (Al₂O₃), and hafnium oxide (HfO₂).

In addition, the semiconductor layer 100, the source electrode 200, and the first interlayer 410 may be electrically connected to each other, and the semiconductor layer 100, the drain electrode 300, and the second interlayer 420 may be electrically connected to each other.

In addition, the source electrode 200 and the first interlayer 410 may be in contact with each other, and the semiconductor layer 100, the drain electrode 300, and the second interlayer 420 may be in contact with each other.

Another aspect of the present disclosure provides a method for manufacturing a thin-film transistor, the method comprising: (a) forming a semiconductor layer 100 comprising a tellurium-based amorphous p-type semiconductor; (b) forming an interlayer 400 comprising a first interlayer 410 and a second interlayer 420 on the semiconductor layer 100; and (c) forming a source electrode 200 and a drain electrode 300 on the first interlayer 410 and the second interlayer 420, respectively.

In addition, the method may further comprise, before step (a), (a′) providing a substrate comprising a gate electrode 500 and an insulating layer 600, and the semiconductor layer 100 of step (a′) may be formed on the insulating layer 600 of the substrate.

In addition, the interlayer 400 of step (b) may be formed by any one selected from the group consisting of thermal evaporation, sputtering, and atomic layer deposition (ALD).

In addition, the interlayer in step (b) may be formed by thermal evaporation, and the thermal evaporation may be carried out at a temperature in a range of room temperature to 200° C.

In addition, the thermal evaporation may be carried out under a vacuum pressure of 10⁻³ Torr or less.

In addition, the method may further comprise, after step (b), (b′) annealing the semiconductor layer 100 in air at a temperature in a range of 60 to 300° C., preferably 130 to 250° C.

The present disclosure can provide a TFT exhibiting excellent electrical performance with improved electron field effect mobility and on-current value by comprising a Te interlayer.

### BRIEF DESCRIPTION OF THE DRAWINGS

These drawings are for the purpose of describing exemplary embodiments of the present disclosure, and therefore the technical idea of the present disclosure should not be construed as being limited to the accompanying drawings:

FIG. 1 shows the structure of a thin-film of Preparation Example 1-2 of the present disclosure.

FIG. 2 shows the results of Raman spectrum measurement and types of lattice vibration for the Te thin-film of Preparation Example 1-2 of the present disclosure.

FIG. 3 is the results of thickness measurements for the Te thin-film of Preparation Example 1-2 of the present disclosure.

FIG. 4A is an AFM photograph of the surface of the Te thin-film of Preparation Example 1-1 measured immediately after deposition.

FIG. 4B is an AFM photograph of the surface of the Te thin-film of Preparation Example 1-2.

FIG. 4C is an AFM photograph of the surface of the Te thin-film of Preparation Example 1-3.

FIG. 5A is a cross-sectional view of a TeOₓ TFT using a thermal evaporation deposition process according to Comparative Example 1.

FIG. 5B is a cross-sectional view of a TeOₓ TFT with a Te interlayer inserted according to Example 1.

FIG. 6A is a graph showing the output characteristics of the TeOₓ TFT of Comparative Example 1 and the TeOₓ TFT with a Te interlayer inserted according to Example 1 of the present disclosure.

FIG. 6B is a graph showing the contact resistance characteristics of the TeOₓ TFT of Comparative Example 1 and the inserted Te interlayer according to Example 1 of the present disclosure.

FIG. 7 is a graph showing the output characteristics of the TeOₓ TFT of Comparative Example 1 and the TeOₓ TFT with the inserted Bi interlayer according to Example 2 of the present disclosure.

FIG. 8 is a graph showing the output characteristics of the TeOₓ TFT of Comparative Example 1 and the TeOₓ TFT with the Sb interlayer inserted according to Example 3 of the present disclosure.

FIG. 9 is a graph showing the output characteristics of the TeOₓ TFT of Comparative Example 1 and the TeOₓ TFT with a Se interlayer inserted according to Example 2 of the present disclosure.

### DESCRIPTION OF THE PREFERRED EMBODIMENTS

Herein after, embodiments of the present disclosure will be described in detail with reference to the accompanying drawings in such a manner that the ordinarily skilled in the art can easily implement the embodiments of the present disclosure.

The description given below is not intended to limit the present disclosure to specific Examples. In relation to describing the present disclosure, when the detailed description of the relevant known technology is determined to unnecessarily obscure the gist of the present disclosure, the detailed description may be omitted.

The terminology used herein is for the purpose of describing particular examples only and is not intended to limit the scope of the present disclosure. As used herein, the singular forms “a”, “an”, and “the” are intended to comprise the plural forms as well unless the context clearly indicates otherwise. It will be further understood that the terms “comprise” or “have” when used in the present disclosure specify the presence of stated features, integers, steps, operations, elements and/or combinations thereof, but do not preclude the presence or addition of one or more other features, integers, steps, operations, elements, and/or combinations thereof.

Terms comprising ordinal numbers used in the specification, “first”, “second”, etc. can be used to discriminate one component from another component, but the order or priority of the components is not limited by the terms unless specifically stated. These terms are used only for the purpose of distinguishing a component from another component. For example, without departing from the scope of the present disclosure, a first component may be referred as a second component, and a second component may be also referred to as a first component.

In addition, when it is mentioned that a component is “formed” or “stacked” on another component, it should be understood such that one component may be directly attached to or directly stacked on the front surface or one surface of the other component, or an additional component may be disposed between them.

Hereinafter, a tellurium oxide semiconductor thin-film transistor comprising tellurium interlayer and method for manufacturing the same will be described in detail. However, those are described as examples, and the present disclosure is not limited thereto and is only defined by the scope of the appended claims.

One aspect of the present disclosure provides a thin-film transistor, the thin-film transistor 10 comprising: a semiconductor layer 100 comprising a tellurium-based amorphous p-type semiconductor; a source electrode 200 and a drain electrode 300 located spaced apart from each other; and an interlayer 400 comprising a first interlayer 410 located between the semiconductor layer 100 and the source electrode 200 and a second interlayer 420 located between the semiconductor layer 100 and the drain electrode 300, wherein the first interlayer 410 and the second interlayer 420 each independently comprise at least one interlayer element selected from the group consisting of a Group 14 element, a Group 15 element, and a Group 16 element of the periodic table.

In addition, the interlayer element may comprise at least one element selected from the group consisting of tellurium (Te), bismuth (Bi), antimony (Sb), and selenium (Se).

In addition, the tellurium-based amorphous p-type semiconductor may comprise a chalcogen atom comprising at least one selected from the group consisting of a selenium (Se) atom and a sulfur (S) atom; and a tellurium composite comprising a tellurium (Te)atom and a tellurium oxide.

In addition, the chalcogen atom may be alloyed with the tellurium composite.

In addition, the tellurium-based amorphous p-type semiconductor may be represented by Chemical Formula 1.

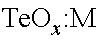

wherein in Chemical Formula 1, M is a sulfur atom (S) or a selenium atom (Se), and x is 0.8≤x≤1.7.

In addition, the tellurium oxide may comprise a tellurium monoxide (TeO) and a tellurium dioxide (TeO₂).

In addition, the tellurium atom of the tellurium-based amorphous p-type semiconductor may comprise an ionization state of Te⁴⁺, and an ionization state of Te²⁺ and a non-ionization state of Te⁰.

In addition, the selenium atom (Se) may comprise an ionization state of Se²⁻.

In addition, the semiconductor may be in an oxygen-deficient state.

In addition, the source electrode may comprise at least one selected from the group consisting of gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotube (CNT), silver nanowire (Ag NW), indium tin oxide (ITO), and poly(3,4-ethylenedioxythiophene) polystyrene sulfonate (PEDOT:PSS).

In addition, the drain electrode may comprise at least one selected from the group consisting of gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotube (CNT), silver nanowire (Ag NW), indium tin oxide (ITO), and poly(3,4-ethylenedioxythiophene) polystyrene sulfonate (PEDOT:PSS).

In addition, the thin-film transistor may further comprise a gate electrode 500, and the gate electrode 500 may comprise at least one selected from the group consisting of n-doped silicon (n-doped Si), p-doped silicon (p-doped Si), gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotubes (CNT), silver nanowires (Ag NW), indium tin oxide (ITO), and poly(3,4-ethylenedioxythiophene) polystyrene sulfonate (PEDOT:PSS).

In addition, the thin-film transistor may further comprise an insulating layer 600 between the semiconductor layer 100 and the gate electrode 500, and the insulating layer 600 may comprise at least one selected from the group consisting of silicon dioxide, glass, quartz, alumina, silicon carbide, magnesium oxide, polyethylene naphthalate (PEN), polyethylene terephthalate (PET), polystyrene (PS), polyimide (PI), polyvinyl chloride (PVC), polyvinylpyrrolidone (PVP), polyethylene (PE), silicon oxide (SiO₂), germanium, polyvinyl alcohol (PVA), polymethyl methacrylate (PMMA), zirconium oxide (ZrO₂), aluminum oxide (Al₂O₃), and hafnium oxide (HfO₂).

In addition, the semiconductor layer 100, the source electrode 200, and the first interlayer 410 may be electrically connected to each other, and the semiconductor layer 100, the drain electrode 300, and the second interlayer 420 may be electrically connected to each other.

In addition, the source electrode 200 and the first interlayer 410 may be in contact with each other, and the semiconductor layer 100, the drain electrode 300, and the second interlayer 420 may be in contact with each other.

Another aspect of the present disclosure provides a method for manufacturing a thin-film transistor, the method comprising: (a) forming a semiconductor layer 100 comprising a tellurium-based amorphous p-type semiconductor; (b) forming an interlayer 400 comprising a first interlayer 410 and a second interlayer 420 on the semiconductor layer 100; and (c) forming a source electrode 200 and a drain electrode 300 on the first interlayer 410 and the second interlayer 420, respectively.

In addition, the method may further comprise, before step (a), (a′) providing a substrate comprising a gate electrode 500 and an insulating layer 600, and the semiconductor layer 100 of step (a′) may be formed on the insulating layer 600 of the substrate.

In addition, the interlayer 400 of step (b) may be formed by any one selected from the group consisting of thermal evaporation, sputtering, and atomic layer deposition (ALD).

In addition, the interlayer 400 in step (b) may be formed by thermal evaporation, and the thermal evaporation may be carried out at a temperature in a range of room temperature to 200° C.

In addition, the thermal evaporation may be carried out under a vacuum pressure of 10⁻³ Torr or less. When a vacuum pressure is higher than 10⁻³ Torr, it may contain impurities, which is undesirable.

In addition, when performing the thermal evaporation, the thermal evaporation rate may be 0.1 to 100 Å/s. When the thermal evaporation rate is less than 0.1 Å/s, the process time for thin-film deposition is too long, which is undesirable. When it exceeds 100 Å/s, the surface roughness of the thin-film increases, which is undesirable.

In addition, the method may further comprise, after step (b), (b′) annealing the semiconductor layer 100 in air at a temperature in a range of 60 to 300° C., preferably 130 to 250° C. When the annealing temperature is less than 60° C., crystallization may not progress sufficiently, which may result in structural non-uniformity of the thin-film and deterioration of charge transfer characteristics, which is undesirable. When it exceeds 300° C., crystal structure collapse and deterioration of electronic characteristics may occur due to thermal decomposition and loss of volatile components, which is undesirable.

The present disclosure can provide a TFT exhibiting excellent electrical performance with improved electron field effect mobility and on-current value by comprising a Te interlayer.

### Examples

Hereinafter, the examples of the present disclosure will be described. However, the examples are for illustrative purposes, and the scope of the present disclosure is not limited by the examples.

### Preparation Example: Preparation of Te Thin-Films

### Preparation Example 1-1: Without Annealing

Commercially available Te powder (purity 99% or higher) was used as an evaporation source to deposit Te semimetal thin-films. The thin-films were deposited using a conventional thermal evaporator. The substrate temperature was 25° C., and the vacuum pressure before evaporation was 10⁻³ Torr or less. The distance between the substrate and the boat loaded with Te powder ranged from 2 to 50 cm. The deposition rate was 0.1 to 2.5 Å s⁻¹. The thickness of the Te thin-film (10.5 nm) was monitored during deposition.

### Preparation Example 1-2: 100° C. Annealing

The Te thin-film sample as-deposited of Preparation Example 1-1 was annealed at 100° C. for 0.5 h in a N₂-filled glove box to form Te semimetal thin-films.

### Preparation Example 1-3: 200° C. Annealing

The as-deposited Te thin-film sample from Preparation Example 1-1 was annealed at 200° C. for 0.5 h in a N₂-filled glove box to form Te semimetal thin-films.

### Example: Fabrication of p-Channel TFTs Using Thermal Evaporation Deposition

### Example 1: Insertion of Te Interlayer

Commercially available TeOₓ and Se powders (purity ≥99%) were used as evaporation sources to deposit a Se-alloyed TeOₓ-based semiconductor thin-film. The thin-film was deposited using a conventional thermal evaporator. The substrate temperature was 25° C., and the vacuum pressure prior to evaporation was 10⁻³ Torr or less. The distance between the substrate and the TeOₓ-loaded boat was from 2 to 50 cm. The deposition rate was 0.1 to 2.5 Å s⁻¹. The deposited sample was annealed at 225° C. for 0.5 h in air atmosphere to form a Se-alloyed TeOₓ-based semiconductor thin film. Commercially available Te powders (purity 99%) were then used as evaporation sources to form Te interlayer. The thin-film were deposited using the conventional thermal evaporator. The substrate temperature was 25° C., and the vacuum pressure before evaporation was less than 10⁻³ Torr. The distance between the substrate and the Te-loaded boat was 2 to 50 cm. The deposition rate was 0.1 to 1.5 Å s⁻¹ to form a Te interlayer thin-film. After that, the Te interlayer thin-film was optimized by performing an annealing process at 100° C. for 0.5 h in air. After that, Ni was thermally evaporated as source/drain electrodes on the Te interlayer, respectively, to fabricate a TeOₓ TFT with the Te interlayers inserted.

### Example 2: Bi Interlayer Insertion

TeOₓ TFTs with an interlayer were fabricated in the same manner as Example 1, except that a Bi evaporation source was used to form the interlayer.

### Example 3: Sb Interlayer Insertion

TeOₓ TFTs with an interlayer were fabricated in the same manner as Example 1, except that a Sb evaporation source was used to form the interlayer.

### Example 4: Se Interlayer Insertion

TeOₓ TFTs with an interlayer were fabricated in the same manner as Example 1, except that a Se evaporation source was used to form the interlayer.

### Comparative Example 1: Without Forming a Te Interlayer

TeOₓ TFTs were fabricated in the same manner as Example 1, except that the Te interlayer deposition process was omitted instead of the Te interlayer deposition process in Example 1.

### Test Example

### Test Example 1: Te Interlayer Structure

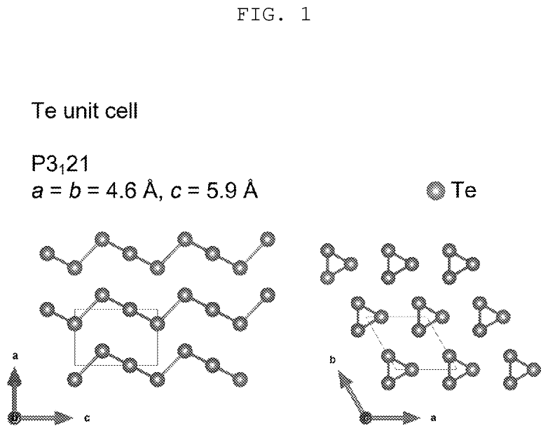

FIG. 1 shows the structure of a thin-film of Preparation Example 1-2 of the present disclosure. Referring to FIG. 1, the deposited Te interlayer has a P3₁21 structure and comprises a material with a unit cell of a=b=4.6 Å, and c=5.9 Å.

### Test Example 2: Confirmation of Te Interlayer Structure

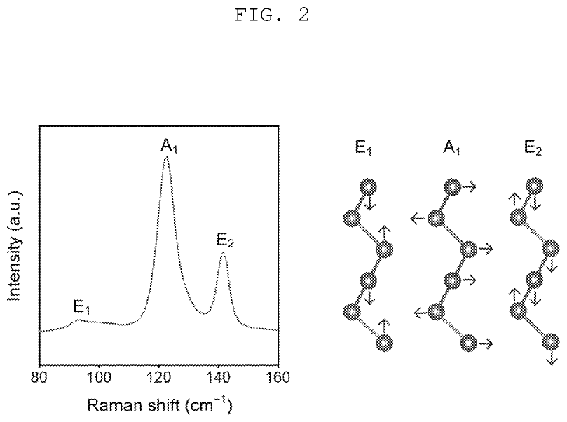

FIG. 2 shows the results of Raman spectrum measurement and types of lattice vibration for the Te thin-film of Preparation Example 1-2 of the present disclosure. Referring to FIG. 2, peaks at 94, 123, and 142 cm⁻¹ were observed, which were confirmed that these peaks correspond to the E₁, A₁, and E₂ lattice vibration peaks of the Te thin-film, respectively.

### Test Example 3: Confirmation of Te Interlayer Thickness

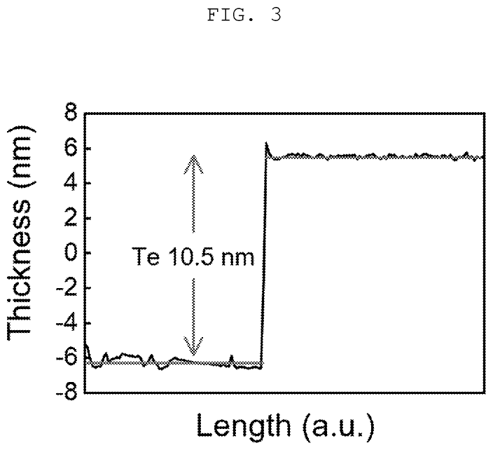

FIG. 3 is the results of thickness measurements for the Te thin-film of Preparation Example 1-2 of the present disclosure. Referring to FIG. 3, atomic force microscopy (AFM) analysis shows that a Te thin-film with a thickness 10.5 nm was formed with a uniform thickness.

### Test Example 4: Confirmation of Annealing Effect of Te Interlayer

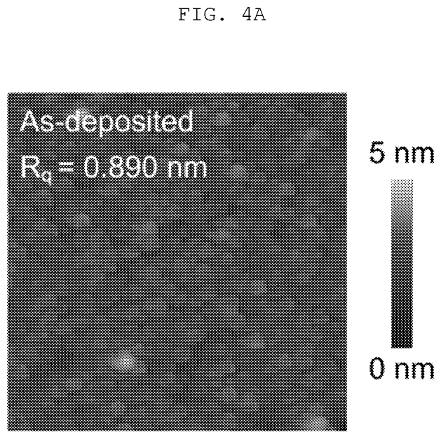

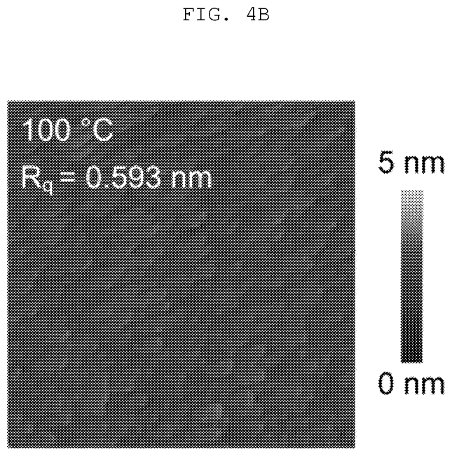

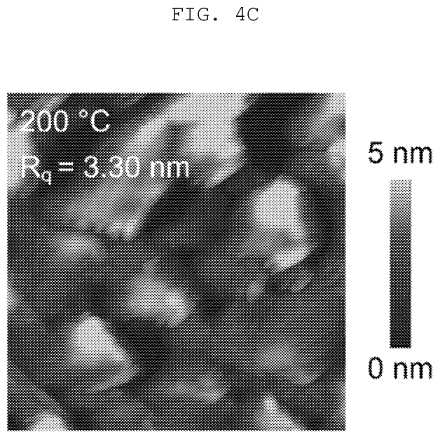

FIG. 4A is an AFM photograph of the surface of the Te thin-film of Preparation Example 1-1 measured immediately after deposition. FIG. 4B is an AFM photograph of the surface of the Te thin-film of Preparation Example 1-2. FIG. 4C is an AFM photograph of the surface of the Te thin-film of Preparation Example 1-3. Referring to FIGS. 4A, 4B, and 4C, in Preparation Example 1-1, the Te thin-film without annealing exhibited a roughness of 0.890 nm. In Preparation Example 1-2, the Te thin-film annealed at 100° C. for 0.5 hours exhibited a roughness of 0.593 nm. In Preparation Example 1-3, the Te thin-film annealed at 200° C. for 0.5 hours exhibited a roughness of 3.30 nm. It was confirmed that undergoing the annealing process at 100° C. in Preparation Example 1-2 is optimal.

### Test Example 5: Electron Transport Characteristics of TeOₓ TFTs with Insertion Te Interlayer

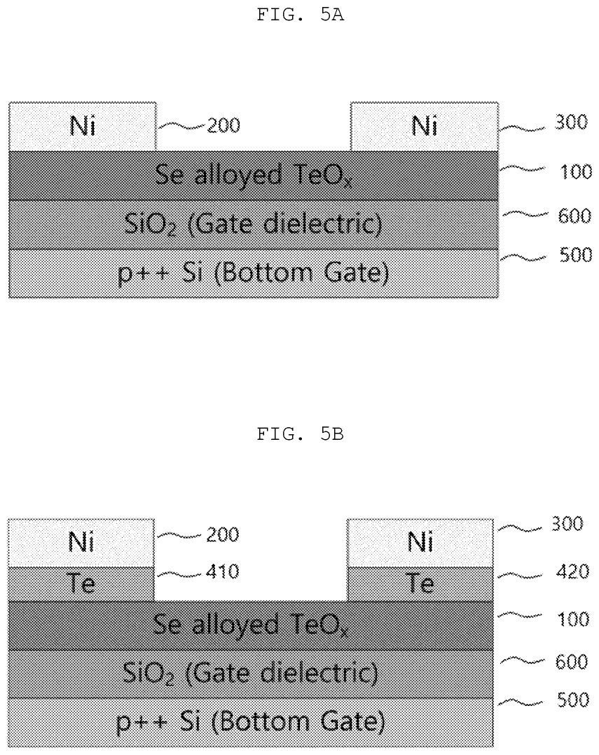

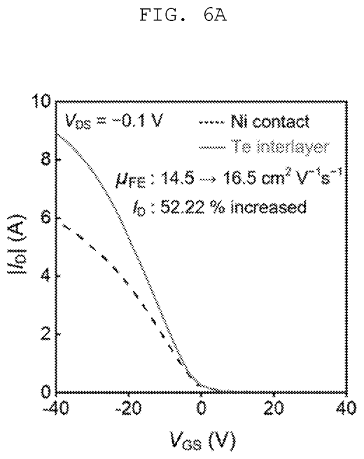

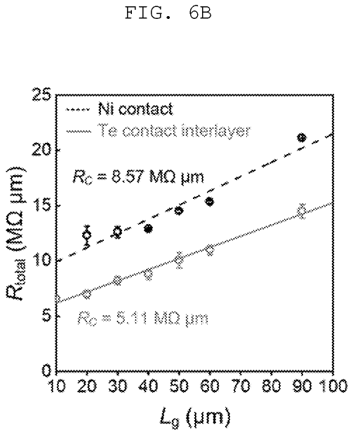

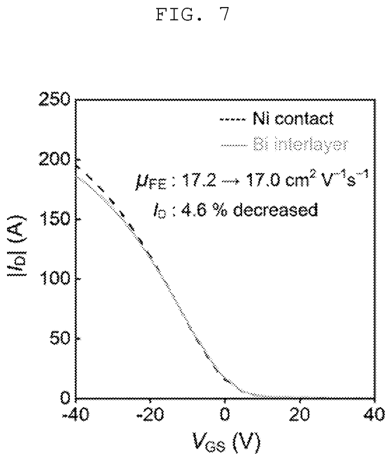

FIG. 5A is a cross-sectional view of a TeOₓ TFT using a thermal evaporation deposition process according to Comparative Example 1. FIG. 5B is a cross-sectional view of a TeOₓ TFT with a Te interlayer inserted according to Example 1. FIG. 6A is a graph showing the output characteristics of the TeOₓ TFT of Comparative Example 1 and the TeOₓ TFT with a Te interlayer inserted according to Example 1 of the present disclosure. Referring to FIGS. 5A, 5B, and 6A, it was confirmed that the TeOₓ TFT with Te an inserted interlayer (Example 1) exhibited a 52.22% improvement in on-current value, and an improvement in electron mobility from 14.5 cm²/V·s to 16.5 cm²/V·s compared to the TeOₓ TFT without the Te inserted interlayer (Comparative Example 1).

### Test Example 6: Contact Resistance Characteristics

FIG. 6B is a graph showing the contact resistance characteristics of the TeOₓ TFT of Comparative Example 1 and the TeOₓ TFT with the inserted Te interlayer according to Example 1 of the present disclosure. Referring to FIG. 6B, it can be confirmed that the contact resistance improves from 8.57 MΩ·μm to 5.11 MΩ·μm when the Te interlayer is inserted.

### Test Example 7: Electron Transport Characteristics of the TeOₓ TFT with Inserted Bi Interlayer

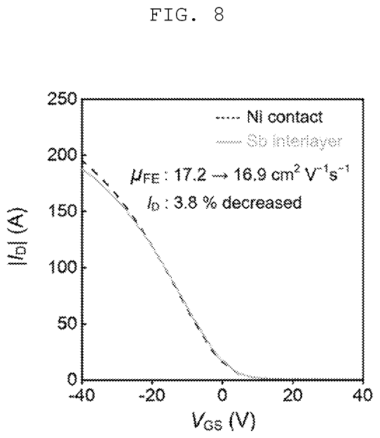

FIG. 7 is a graph showing the output characteristics of the TeOₓ TFT of Comparative Example 1 and the TeOₓ TFT with the inserted Bi interlayer according to Example 2 of the present disclosure. Referring to FIG. 7, the TeOₓ TFT with an inserted Bi interlayer (Example 1) exhibited a 4.6% decrease in on-state current, and an improvement in electron mobility from 17.2 cm²/V·s to 17.0 cm²/V·s compared to the TeOₓ TFT without the inserted Te interlayer (Comparative Example 1).

### Test Example 8: Electron Transport Characteristics of TeOₓ TFTs with Sb Interlayer

FIG. 8 is a graph showing the output characteristics of the TeOₓ TFT of Comparative Example 1 and the TeOₓ TFT with the inserted Sb interlayer according to Example 3 of the present disclosure. Referring to FIG. 8, the TeOₓ TFT with a Bi interlayer (Example 1) exhibited a 3.8% decrease in on-state current and a decrease in electron mobility from 17.2 cm²/V·s to 16.9 cm²/V·s compared to the TeOₓ TFT without the Te interlayer (Comparative Example 1).

### Test Example 9: Electron Transport Characteristics of TeOₓ TFTs with Se Interlayers

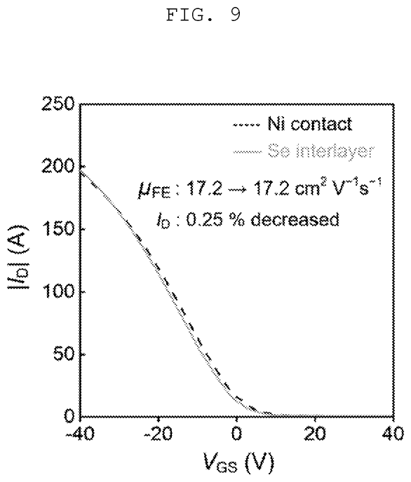

FIG. 9 is a graph showing the output characteristics of the TeOₓ TFT of Comparative Example 1 and the TeOₓ TFT with the inserted Se interlayer according to Example 2 of the present disclosure. Referring to FIG. 9, it was confirmed that the TeOₓ TFT with the inserted Bi interlayer (Example 1) exhibited a 0.25% decrease in on-current value, and a retention in electron mobility from 17.2 cm²/V·s to 17.2 cm²/V·s compared to the TeOₓ TFT without the inserted Te interlayer (Comparative Example 1).

The scope of the present disclosure is defined by the following claims rather than the above detailed description, and all changes or modifications derived from the meaning and scope of the claims and their equivalent concepts should be interpreted as falling into the scope of the present disclosure.

What is claimed is:

1. A thin-film transistor comprising:
a semiconductor layer comprising a tellurium-based amorphous p-type semiconductor;
a source electrode and a drain electrode located spaced apart from each other; and
an interlayer comprising a first interlayer located between the semiconductor layer and the source electrode and a second interlayer located between the semiconductor layer and the drain electrode,
wherein the first interlayer and the second interlayer each independently comprise at least one interlayer element selected from the group consisting of a Group 14 element, a Group 15 element, and a Group 16 element of the periodic table.

2. The thin-film transistor of claim 1, wherein the interlayer element comprises at least one element selected from the group consisting of tellurium (Te), bismuth (Bi), antimony (Sb), and selenium (Se).

3. The thin-film transistor of claim 1, wherein the tellurium-based amorphous p-type semiconductor comprises:
a chalcogen atom comprising at least one selected from the group consisting of a selenium (Se) atom and a sulfur (S) atom; and
a tellurium composite comprising a tellurium (Te) atom and a tellurium oxide.

4. The thin-film transistor of claim 3, wherein the chalcogen atom is alloyed with the tellurium composite.

5. The thin-film transistor of claim 3, wherein the tellurium-based amorphous p-type semiconductor is represented by Chemical Formula 1. 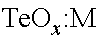
wherein in Chemical Formula 1, M is a sulfur (S) atom or a selenium (Se) atom, and
x is 0.8≤x≤1.7.

6. The thin-film transistor of claim 3, wherein the tellurium oxide comprises a tellurium monoxide (TeO) and a tellurium dioxide (TeO₂).

7. The thin-film transistor of claim 1, wherein the tellurium atom of the tellurium-based amorphous p-type semiconductor comprises an ionization state of Te⁴⁺, and an ionization state of Te²⁺ and a non-ionization state of Te⁰.

8. The thin-film transistor of claim 3, wherein the selenium atom (Se) comprises an ionization state of Se²⁻.

9. The thin-film transistor of claim 1, wherein the semiconductor is in an oxygen-deficient state.

10. The thin-film transistor of claim 1, wherein the source electrode comprises at least one selected from the group consisting of gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotube (CNT), silver nanowire (Ag NW), indium tin oxide (ITO), and poly(3,4-ethylenedioxythiophene) polystyrene sulfonate (PEDOT:PSS), and
the drain electrode comprises at least one selected from the group consisting of gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotube (CNT), silver nanowire (Ag NW), indium tin oxide (ITO), and poly(3,4-ethylenedioxythiophene) polystyrene sulfonate (PEDOT:PSS).

11. The thin-film transistor of claim 1, further comprising a gate electrode,
wherein the gate electrode comprises at least one selected from the group consisting of n-doped silicon (n-doped Si), p-doped silicon (p-doped Si), gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotubes (CNT), silver nanowires (Ag NW), indium tin oxide (ITO), and poly(3,4-ethylenedioxythiophene) polystyrene sulfonate (PEDOT:PSS).

12. The thin-film transistor of claim 11, further comprising an insulating layer between the semiconductor layer and the gate electrode,
wherein the insulating layer comprises at least one selected from the group consisting of silicon dioxide, glass, quartz, alumina, silicon carbide, magnesium oxide, polyethylene naphthalate (PEN), polyethylene terephthalate (PET), polystyrene (PS), polyimide (PI), polyvinyl chloride (PVC), polyvinylpyrrolidone (PVP), polyethylene (PE), silicon oxide (SiO₂), germanium, polyvinyl alcohol (PVA), polymethyl methacrylate (PMMA), zirconium oxide (ZrO₂), aluminum oxide (Al₂O₃), and hafnium oxide (HfO₂).

13. The thin-film transistor of claim 1, wherein the semiconductor layer, the source electrode, and the first interlayer are electrically connected to each other, and
the semiconductor layer, the drain electrode, and the second interlayer are electrically connected to each other.

14. The thin-film transistor of claim 1, wherein the source electrode and the first interlayer are in contact with each other, and
the semiconductor layer, the drain electrode, and the second interlayer are in contact with each other.

15. A method for manufacturing a thin-film transistor, the method comprising:
(a) forming a semiconductor layer comprising a tellurium-based amorphous p-type semiconductor;
(b) forming an interlayer comprising a first interlayer and a second interlayer on the semiconductor layer; and
(c) forming a source electrode and a drain electrode on the first interlayer and the second interlayer, respectively

16. The method of claim 15, further comprising, before step (a), (a′) providing a substrate comprising a gate electrode and an insulating layer,
wherein the semiconductor layer of step(a′) is formed on the insulating layer of the substrate.

17. The method of claim 15, wherein the interlayer of step (b) is formed by any one selected from the group consisting of thermal evaporation, sputtering, and atomic layer deposition (ALD).

18. The method of claim 17, wherein the interlayer in step (b) is formed by thermal evaporation,
Wherein the thermal evaporation is carried out at a temperature in a range of room temperature to 200° C.

19. The method of claim 18, wherein the thermal evaporation is carried out under a vacuum pressure of 10⁻³ Torr or less.

20. The method of claim 15, further comprising, after step (b), (b′) annealing the semiconductor layer in air at a temperature in a range of 60 to 300° C.
